(19) United States
(12) Patent Application Publication
(10) Pub. No.: US 2015/0070089 A1
(43) Pub. Date: Mar. 12, 2015

(54) ADAPTIVE NONLINEAR MODEL LEARNING

(71) Applicant: MagnaCom Ltd., Moshav Ben Shemen (IL)

(72) Inventors: Amir Eliaz, Moshav Ben Shemen (IL); Ilan Reuven, Ganey Tikva (IL); Gal Pitarasho, Tel Aviv (IL)

(21) Appl. No.: 14/481,108

(22) Filed: Sep. 9, 2014

Related U.S. Application Data
(60) Provisional application No. 61/875,174, filed on Sep. 9, 2013.

(51) Int. Cl. H03F 1/32

(52) U.S. Cl. CPC H03F 1/3258; H03F 2201/3233
USPC 330/149

(57) ABSTRACT

In accordance with an example implementation of this disclosure, a receiver may comprise a signal reconstruction circuit and a nonlinearity modeling circuit. The nonlinearity modeling circuit may be operable to generate a look-up table (LUT)-based model of nonlinear distortion present in a received signal. An entry of the LUT may comprise a signal power parameter value and a distortion parameter value. The signal reconstruction circuit may be operable to generate one or more candidates for a transmitted signal corresponding to the received signal. The signal reconstruction circuit may be operable to distort the one or more candidates according to the model, the distortion resulting in one or more reconstructed signals. The signal reconstruction circuit may be operable to decide a best one of the candidates based on the one or more reconstructed signals.

### CLAIM OF PRIORITY

The application claims the benefit of priority to U.S. provisional patent application Ser. No. 61/875,174 titled “Adaptive Nonlinearity Model Learning,” which is hereby incorporated by reference.

### BACKGROUND

High spectral efficiency communication systems may be affected by nonlinear distortion that degrades communication performance (e.g., measured as capacity, system gain, and/or the like). The nonlinear distortion may originate in the transmitter, the channel, and/or the receiver. The nonlinearities may consist of phase noise from, for example, frequency sources needed for up/down conversion of the modulated signal) and/or signal envelope distortion (e.g., compression) caused, for example, by elements such as amplifier, analog circuits, frequency mixers and transceivers that may be used for transforming electronic signals to and from the propagation medium (e.g., copper, wireless or fiber optic cable). Conventional methods and systems for dealing with such nonlinearities have limited effectivity and suffer from several disadvantages.

### BRIEF SUMMARY OF THE DISCLOSURE

Aspects of the present disclosure are directed to methods and systems for improving performance of digital communications systems that are subject to nonlinear distortion.

Various advantages, aspects, and novel features of the present disclosure, as well as details of an illustrated embodiment thereof, will be more fully understood from the following description and drawings.

### BRIEF DESCRIPTION OF DRAWINGS

FIG. 1 depicts a transmitter in accordance with an example implementation of this disclosure.

FIG. 2 depicts a receiver in accordance with an example implementation of this disclosure.

FIG. 3 depicts look-up tables for realizing a first example nonlinear distortion model.

FIG. 4 is a flowchart illustrating an example process for signal reception using the nonlinear model of FIG. 3.

FIG. 5 is a flowchart illustrating an example process for adaptation of the nonlinear model of FIG. 3.

FIG. 6 depicts a look-up table for realizing a second example nonlinear distortion model.

FIG. 7 is a flowchart illustrating an example process for signal reception using the nonlinear model of FIG. 6.

FIG. 8 is a flowchart illustrating an example process for signal reception using the nonlinear model of FIG. 6.

### DETAILED DESCRIPTION

As utilized herein, the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As utilized herein, “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}. As utilized herein, the terms “e.g.,” and “for example” set off lists of one or more non-limiting examples, instances, or illustrations. As utilized herein, circuitry is “operable” to perform a function whenever the circuitry comprises the necessary hardware and code (if any is necessary) to perform the function, regardless of whether performance of the function is disabled, or not enabled, by some user-configurable setting.

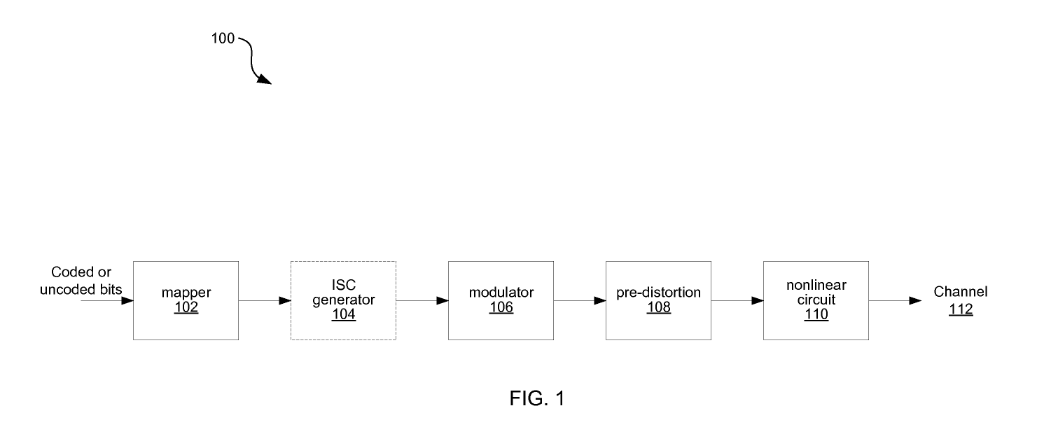

FIG. 1 depicts a transmitter in accordance with an example implementation of this disclosure. The example transmitter 100 comprises a mapper 102, an (optional) ISC generator 104, a single-carrier or multi-carrier (e.g., using orthogonal frequency division multiplexing) modulator circuit 106, a pre-distortion circuit 108, and a circuit 110 that introduces nonlinear distortion.

The mapper 102 is operable to map coded or uncoded data bits to symbols of any constellation scheme such as N-QAM, N-PAM, N-PSK (where ‘NI’ is an integer).

The symbols output by mapper 102 may be fed into the ISC Generator 104 which generates samples that introduce symbol correlation. The ISC generator 104 may comprise, for example, a pulse shaping filter. The ISC generator 104 may be present in faster than Nyquist (FTN) implementations.

The signal output by the mapper 102 (or ISC generator 104, when present) drives the modulator 106 which modulates the signals on to one (single carrier) or more (multi-carrier) carriers. The modulator 106 may comprise one or more mixers, local oscillators, phase shifters, fast Fourier transform circuits, inverse fast Fourier transform circuits, filters, cyclic prefix insertion circuit, windowing circuit, and/or the like.

The modulated signal output by modulator 106 may be input to the pre-distortion circuit 108 and then to the nonlinear circuit 110. The nonlinear circuit 110 may, for example, comprise a power amplifier. The pre-distortion circuit 108 may be configured to condition/pre-distort to optimize the composite nonlinear distortion (e.g., perform a soft-clip) which is defined as the overall distortion introduced by the pre-distortion circuitry 108 and the nonlinear circuit 110 (denoted g( )). A receiver may use the composite nonlinear model to tolerate the nonlinear distortion present in signals received from the transmitter 100. Therefore, because the memory length of nonlinear model may have a direct impact on decoder complexity, the pre-distortion circuit 108 may be configured to trade complexity with performance. In this regard, a goal of the configuration of the pre-distortion circuit 108 may be to equalize (shorten) the memory length of the nonlinear portion of the composite response. Although another pre-distortion goal may be to minimize the distortion level, this latter goal may conflict with the goal of reducing the memory length of the nonlinear portion of the composite response. That is, it is possible that pre-distortion configured to minimize the distortion memory length may actually increase the distortion error vector magnitude (EVM). Even in such case, the receiver may be aware of the memoryless (or near memoryless) composite distortion model and may be able to exhibit good performance while benefiting from the reduced complexity of the memoryless (or near memoryless) distortion model.

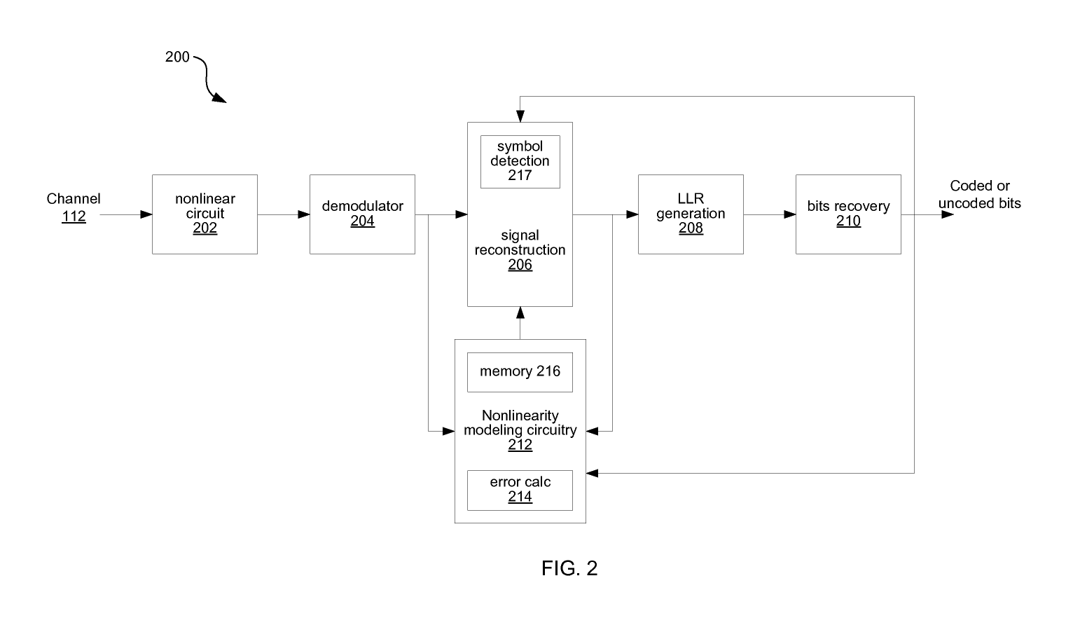

The signal output by nonlinear circuit 110 may pass through a channel 112 comprising multipath, additive white Gaussian noise (AWGN) and/or additional sources of nonlinear distortion prior to reception at the input of a receiver such as receiver 200 of FIG. 2.

Referring to FIG. 2, the receiver 200 comprises a nonlinear circuit 202, a demodulator 204, a signal reconstruction circuit 206, symbol detection circuit 208, and a bit recovery circuit 210, and modeling circuit 212 which models the nonlinear distortion present in the received signal.

The signal received via the channel is input to the nonlinear circuit 202 which may comprise, for example, a low-noise amplifier and one or more filters.

The output of the nonlinear circuit 202 is input to the demodulator 204 which may demodulate the signal in accordance with the modulation scheme used in the transmitter 100 (e.g., single carrier or multi-carrier) to output a digital baseband signal. The demodulator 204 may comprise, for example, one or more mixers, local oscillators, phase shifters, fast Fourier transform circuits, inverse fast Fourier transform circuits, filters, cyclic prefix removal circuit, windowing circuit, and/or the like.

The demodulated baseband signal is then communicated to the signal reconstruction circuit 206 which generates one or more probable symbol candidates based on, for example, Maximum Likelihood (ML) or Maximum a-posteriori (MAP) criteria (e.g., sequence estimation). In an example implementation, the signal reconstruction circuit 206 may use a suboptimal decoding algorithm such as Reduced State Sequence Estimation (RSSE) or bidirectional stack. The Symbol detection circuit 217 provides estimation (hypotheses) for transmitted sequences used for the signal reconstruction. The modeling circuit 212 assists in the signal reconstruction by minimizing the Euclidean distance (or any other metric of the error signal) between the baseband signal and the symbol candidate(s) and, consequently, improving detection performance (e.g., measured as symbol error rate (SER), bit error rate (BER), and/or any other suitable metric). The best symbol sequence candidate (survivor) that has the smallest distance to the received baseband signal is then selected by the symbol detection circuit 217 as the decoded symbol sequence to be used for bits recovery by the bits recover circuit 210 (e.g., comprising a symbol-to-bits demapper and a forward error correction (FEC) decoder). In applications where soft-decision decoding is used (e.g., LDPC), the LLR Generation circuit 208 may generate Log-Likelihood Ratios (LLRs) for driving the bits recovery circuit 210. The LLR generation may involve analyzing several symbol survivors (hypotheses) coming from the symbol detection 217 or other method that provides effective LLRs that may be needed to obtain the coding gain of the coding scheme used. In an example implementation, the recovered bits output by the bit recovery circuit 210 may be feedback to the signal reconstruction circuit 206 for iterative processing of received symbols. Similarly, in an example implementation, the recovered bits may be feedback to the nonlinearity modeling circuitry 212 for use in adapting the nonlinear model.

The received signal experiences the impact of the nonlinear distortion and thus, in an example implementation of this disclosure, may be used to determine the nonlinear distortion model and model parameter values to be used by nonlinearity modeling circuitry 212 for modeling the distortion present in the received signal. In an example implementation, known symbols (e.g., pilots, preamble) and/or unknown data-carrying symbols that have been processed by the signal reconstruction circuit 206 may be used by the nonlinearity modeling circuitry 212 to adapt the nonlinearity model such that it tracks the nonlinear distortion actually experienced by the received signal. In this regard, the nonlinear model may be updated dynamically (adaptive) to eliminate model mismatch and to track changes in the actual distortion experienced by the received signal due, for example, to environmental conditions (e.g., temperature, power supply variations, movement of transmitter and/or receiver, etc.). The use of the nonlinearity model determined by the nonlinearity modeling circuitry 212 may improve detection performance (e.g., measured by, for example, Symbol Error Rate (SER) and Bit Error Rate (BER)).

In an example implementation, the nonlinearity model determined by nonlinearity modeling circuitry 212 may be communicated to the transmitter 100 where it may be used to for configuring pre-distortion circuit 108 (or any other pre-compensation method in other implementations) that may benefit from a known nonlinear model to reduce the overall distortion level (EVM), increase transmitted power, improve spectral mask compliance, and/or reduce the memory associated with the nonlinearity.

Under optimal conditions (i.e., perfect noiseless channel conditions and a nonlinear model that perfectly matches the actual nonlinear distortion in the received signal), the Euclidean distance between the best reconstructed signal (i.e., best “candidate”) and the baseband signal will be zero (i.e., they will be identical). But in case of nonlinear model error (i.e., mismatch between the nonlinear distortion reproduced by the model and the nonlinear distortion actually present in the received signal), the Euclidean distance will be positive (i.e., the best reconstructed signal will not be identical to the received baseband signal). This mismatch may degrade decoding performance. According to an example implementation of this disclosure, the receiver may learn and adapt the overall nonlinear model to improve signal reconstruction accuracy and to improve decoding performance. The error calculation circuitry 214 may generate an error signal that is based on the distance between the reconstructed signal and the baseband signal. The error signal may then be used to update the nonlinear model (i.e., update parameter values for a selected model type and/or select a different model type with different parameters). The nonlinear model may be of any suitable type such as: amplitude-to-amplitude type model (AM/AM), amplitude-to-phase type model (AM/PM), memory-less polynomial type model, memory (full) polynomial type model, Volterra series, Rapp, and/or the like.

For example, where both amplitude and phase distortion depend on instantaneous signal power, a combined AM/AM and AM/PM type model may be used. Such a model may be characterized by a signal power parameter, one or more AM/AM distortion parameters, and one or more AM/PM distortion parameters. Such a model may be realized by, for example, two look-up tables (LUTs) were the first LUT maps a value of the signal power parameter to corresponding value(s) of the one or more AM/AM distortion parameter(s), and the second LUT maps a value of the signal power parameter to corresponding value(s) of the one or more AM/PM distortion parameters. Although an example implementation using two separate LUTs is described here, the combined AM/AM and AM/PM may be realized using a single LUT that maps a signal power parameter to a complex valued representing both the AM/AM distortion parameter and the AM/PM distortion parameter.

Using the polar representation of a complex variable x:

x=|x|· [symbol] (1)

where |x| stands for the absolute value (magnitude) of x and [symbol] (x) denotes the angle of x. The received distorted signal, y, resulting from transmitted signal x can be represented as (omitting time dependence for simplicity of notation (i.e., x=x(t), y=y (t))):

y=ρ(|x|²)·|x|· [symbol] (2)

where ρ(|x|²) and φ(|x|²) represent the AM/AM and AM/PM distortion functions, respectively. In case that the nonlinear distortion is very small, y≅x and consequently ρ(|x|²)≈1, φ(|x|²)≈0 for any x.

A reconstructed signal calculated from a candidate symbol or candidate symbol sequence by nonlinearity modeling circuitry 212 can be represented as:

ŷ=\hat{ρ}(|\hat{x}|²)·|\hat{x}|· [symbol] (3)

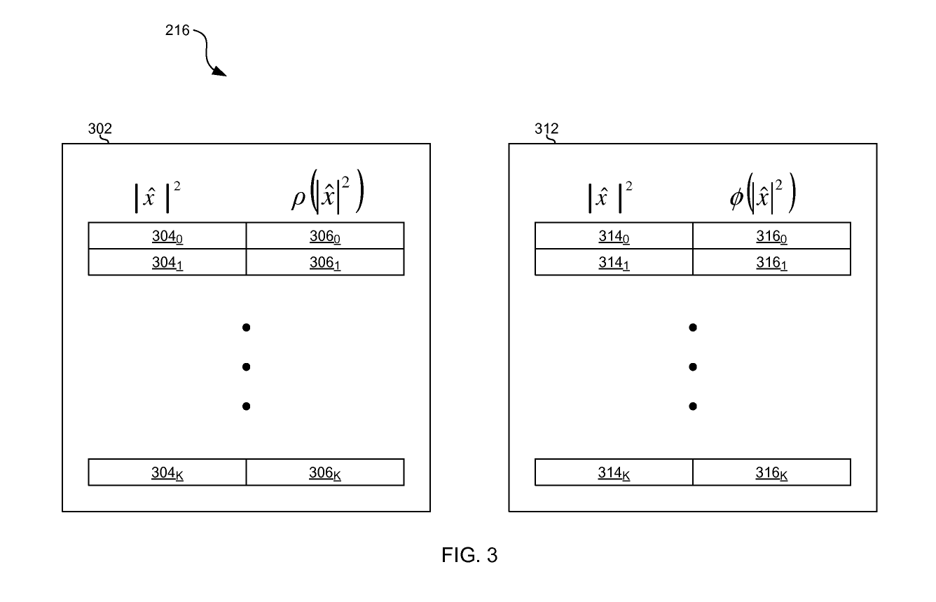

In this expression, \hat{x} denotes the reconstructed signal prior to applying the nonlinear distortion model, and \hat{ρ}(|\hat{x}|²) and \hat{φ}(|\hat{x}|²) represent the estimations of ρ(|x|²) and φ(|x|²) generated by the nonlinearity modeling circuit 212. The combined AM/AM and AM/PM type model may thus be characterized by the signal power parameter |\hat{x}|², the AM/AM parameter \hat{ρ}(|\hat{x}|²), and the AM/PM parameter \hat{φ}(|\hat{x}|²). Referring to FIG. 3, each entry k (for 0≦k≦K) of the first LUT 302 holds: (1) a specific signal power 304ₖ, and (2) the value of \hat{ρ}(|\hat{x}|²) (called out as 306ₖ) that corresponds to the specific signal power 304ₖ. Similarly, each entry k of the second LUT 312 holds: (1) the specific signal power 304ₖ and (2) the value of \hat{φ}(|\hat{x}|²) (called out as 316ₖ) corresponding to the specific signal power 304ₖ. For example, denoting the specific signal power for entry k=0 as |\hat{x}|₀|², entry 0 of the first LUT may store |\hat{x}₀|² and \hat{ρ}(|\hat{x}₀|²) and the second LUT may store |\hat{x}₀|² and \hat{φ}(|\hat{x}₀|²). In another example implementation, a signal power parameter other than |\hat{x}|² may be used and values thereof stored in fields 304₀ . . . 304_{K} of LUT 302 and fields 304₀ . . . 304_{K} of LUT 312. Such alternative signal power parameter may be, for example, a function of the signal level and/or phase such as delayed signal power level (such as delayed AM/PM), a function of signal power at other time instances (to support a nonlinearity model with memory), or a filtered (convolution) of signal instantaneous power samples.

According to an example implementation of this disclosure, the receiver attempts to adapt \hat{ρ}(|\hat{x}|²) and \hat{φ}(|\hat{x}|²) to be as close as possible to the actual ρ(|x|²) and φ(|x|²) manifested in the received signal y (the distortion resulting from pre-distortion circuit 108, nonlinear circuit 110, distortion that may be introduced by the channel, and/or the nonlinear circuit 202). An error that may be used for adapting \hat{ρ}(|\hat{x}|²) can be expressed by the amplitude difference:

eₐₘ(|\hat{x}|²)=|ŷ|^{m},m>0, (4)

and an error that may be used for adapting \hat{φ}(|\hat{x}|²) can be expressed by the phase difference:

eₚₘ(|\hat{x}|²)= [symbol] (ŷ·y*)≈imag(ŷ·y*), (5)

where y* denotes the complex conjugate of y. As an example, the model error signals for a reconstructed signal with a power of |\hat{x}₀|² may be used for adapting the LUT entries associated with signal power |\hat{x}₀|² (i.e., eₐₘ(|\hat{x}₀|²) and eₚₘ(|\hat{x}₀|²) may be used for updating \hat{ρ}(|\hat{x}₀|²) and \hat{φ}(|\hat{x}₀|²), respectively). The nonlinear model error signals may be filtered (e.g., IIR and/or FIR filtering) with the associated LUT entry to overcome channel distortions such as AWGN, phase noise and/or signal reconstruction errors caused by erroneous symbol detection. The amount of averaging may be configured based on a tradeoff between tracking rate and nonlinear model estimation accuracy (at steady state). For example, a first order IIR adaptation (filtering) for the entries corresponding to power |\hat{x}₀|² may be represented as:

\hat{ρ}_{[n]}(|\hat{x}₀|²)=\hat{ρ}_{[n-1]}(|\hat{x}₀|²)+μ·e_{am[n]}(|\hat{x}₀|²), (6)

\hat{φ}_{[n]}(|\hat{x}₀|²)=\hat{φ}_{[n-1]}(|\hat{x}₀|²)+μ·e_{pm[n]}(|\hat{x}₀|²), (7)

where μ denotes the adaptation constant (loop dynamics) and n denotes a time index.

In an example implementation, the model error signals may be weighted according to the signal amplitude to reflect the higher reliability of the error signals when high signal level is received in the presence of AWGN. For example, the error signal may be scaled according to the received signal power |y|², to the reconstructed signal power |ŷ|², or to the combination |ŷ|·|y|:

\hat{ρ}_{[n]}(|\hat{x}₀|²)=\hat{ρ}_{[n-1]}(|\hat{x}₀|²)+μ·|ŷ|·|y|·e_{am[n]}(|\hat{x}₀|²), (8)

\hat{φ}_{[n]}(|\hat{x}₀|²)=\hat{φ}_{[n-1]}(|\hat{x}₀|²)+μ·|ŷ|·|y|·e_{pm[n]}(|\hat{x}₀|²), (9)

In an example implementation, the adaptation rate μ may be changed in real-time according to channel conditions (e.g., signal to noise ratio (SNR), multipath, and/or the like). In an example implementation, changing μ may comprise freezing the adaptation (i.e., μ=0) in case of extremely bad conditions and resuming to normal adaptation rate (i.e., μ≠0) when channel conditions improve.

In an example implementation, benefits may arise from a smooth nonlinear model. Accordingly, a goal of the nonlinearity modeling circuitry 212 in selecting and adapting the nonlinear model may be to select a model type and model parameter values to be as smooth as possible while meeting other constraints. In an example implementation, smoothness of the nonlinear model may be achieved through sharing statistics between adjacent LUT entries using interpolation (smoothing) methods such as linear interpolation, cubic interpolation and spline. The interpolation may increase the tracking rate of the nonlinear model learning and/or improve its accuracy.

In some implementations, signal envelope statistics (distribution) may not be uniform across the signal dynamic range. Specifically, high-amplitude peaks may occur relatively infrequently. Consequently, there are fewer opportunities to estimate the distortion occurring in the received signal at those high signal amplitudes. In an example implementation, this lack of samples at high amplitudes may be overcome by increasing the weight of the model error signals for such high-amplitude signals. This increased weighting may be acceptable due to the associated higher reliability of such signals in an AWGN channel (i.e., higher SNR). Additionally, or alternatively, this may be overcome by performing an extrapolation of the nonlinear model for the amplitudes at which few or no samples have been received. The extrapolation may be based for example on first-order (linear) or higher order (e.g., parabolic, cubic) or spline processing, and may use some a-priori knowledge of the nonlinear model.

In an example implementation, the transmitter 100 may send preambles and/or training sequences and the nonlinear modeling circuitry 212 may be use the preambles and/or training sequences to select the nonlinear model type and/or adapt the values of the nonlinear model's parameters. Accordingly, the transmitter 100 may be configured such that the preambles and/or training sequences it sends are formed for use by the nonlinearity modeling circuitry 212, rather than being configured such that the preambles and/or training sequences it sends are formed for receiver channel estimation and synchronization over a linear channel. In this regard, the transmitter 100 may be configured such that the signal envelope statistics of the training sequences and/or preambles provide enough samples over the entire dynamic range for nonlinear model estimation that is accurate to within a determined error tolerance. In this regard, the transmitter 100 may be configured such that the preambles and/or training sequences provide sufficient samples in areas of the dynamic range in which there may be few or no samples during transmission of actual data. In an example implementation, the receiver may use higher weights for error signals during training and/or preamble sequences to reflect the higher reliability as compared to data transmission and also to emphasize the nonlinear model information in the signal amplitude range(s) that may present in the training and/or preamble sequences and lacking during data transmission.

In an example implementation, the pre-distortion introduced by circuitry 108 is considered as a part of the overall distortion. The pre-distortion, therefore, may affect the adaptation of the nonlinear model. Nonlinear distortion may comprise memory combined with the nonlinearity (e.g., the output signal of the pre-distortion circuit 108 at time instant t may be a function of the signal input to the pre-distortion circuit 108 at that time instant and of earlier input signals). Volterra series is an example of a model for nonlinearity with memory. The use of memory-less nonlinear model may, however, be desirable to reduce complexity of the receiver 200. Accordingly, in an example implementation, the pre-distortion circuit 108 may be configured to reduce (possibly to 0) the length of the memory associated with the nonlinearity, and thus enable the use of a simple nonlinear model at the receiver side that will reduce complexity, improve model accuracy, and improve adaptation rate. Although attempting to configure the pre-distortion circuit 108 to reduce or eliminate the memory of the nonlinearity may result in higher overall distortion of the transmitted signal, there may nonetheless be net increase in performance, as compared to conventional systems, as a result of the use of the pre-distortion circuit 108 in the transmitter and the use of a low-complexity nonlinear model in the nonlinearity modeling circuitry 212.

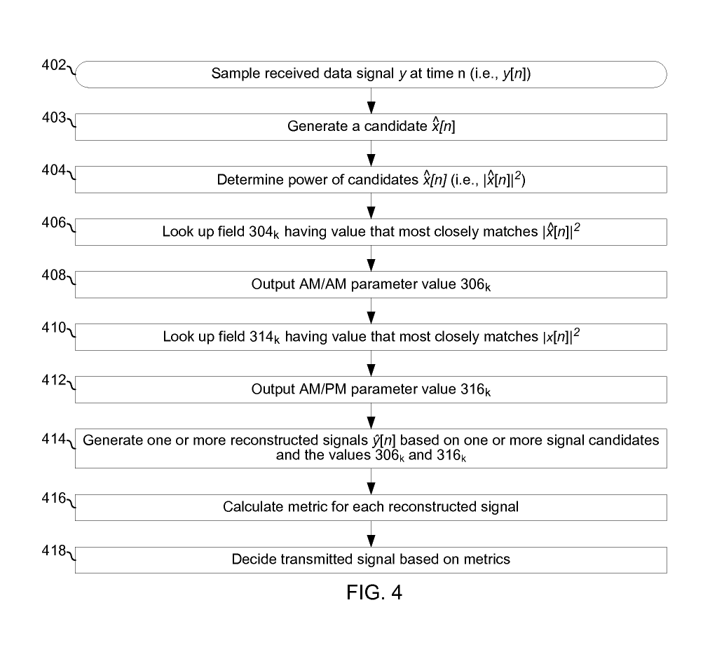

FIG. 4 is a flowchart illustrating an example process for signal reception using the nonlinear model of FIG. 3. In block 402, a received data carrying signal y (i.e., a signal whose contents are not known to the receiver) is sampled at time instant n resulting in a sample y[n]. In block 403 the Signal Reconstruction block 206 provides one or more candidates for the (linear) transmitted signal (denoted \hat{x}[n]) (i.e., each \hat{x}[n]) is a possibility of the linear transmitted signal x[n] that resulted in the received signal y[n]). In block 404, the power of each candidate \hat{x}[n] is calculated as |\hat{x}[n]|². In block 406, the nonlinear modeling circuit 212 accesses the LUT 302 to find the one of the values 304₁ . . . 304_{K} that is closest to |\hat{x}[n]|²(denoted 304ₖ). In block 408, the value 304ₖ is mapped to 306ₖ by the LUT 302. In block 410, the nonlinear modeling circuit 212 accesses the LUT 312 to find the one of the values 314₁ . . . 314_{K} that is closest to |\hat{x}[n]|² (denoted 314ₖ). In block 412, the value 314ₖ is mapped to 316ₖ by the LUT 312. In an example implementation, each 304ₖ may be equal to, or different than, 314ₖ. In block 414, the nonlinear estimation circuit 212 generates one or more reconstructed signals ŷ[n] based on one or more signal candidates and based on the values 306ₖ and 316ₖ from the LUTs 302 and 312 (e.g., using equation (3)). In block 416, a metric is calculated for each of the reconstructed signals. Each of the metrics may be, for example, Euclidean distance between the received signal y[n] and a corresponding one of the reconstructed signals ŷ[n]. In block 418, the symbol detection circuit 217 decides the most-likely transmitted signal based on the calculated metrics.

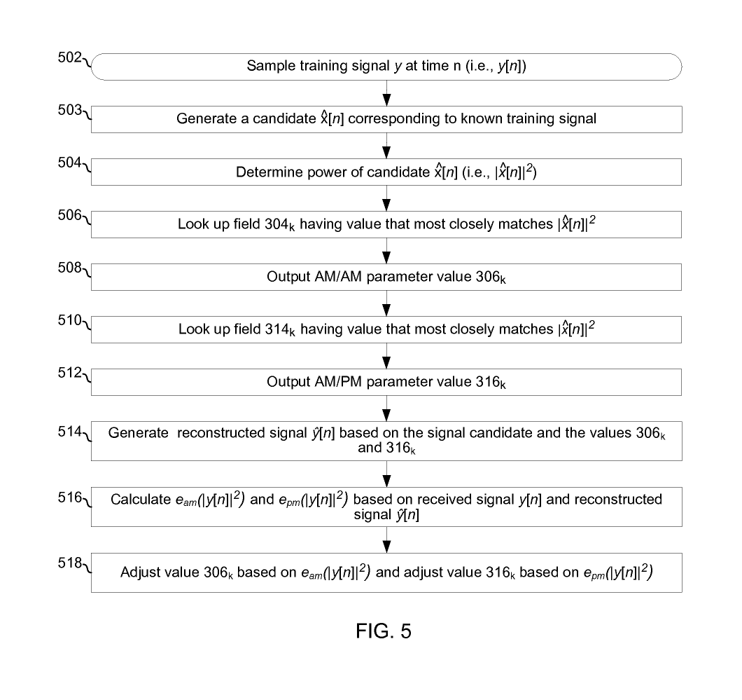

FIG. 5 is a flowchart illustrating an example process for adaptation of the nonlinear model of FIG. 3. In block 502, a received training signal y (e.g., a preamble of a data carrying signal or a dedicated training signal, where the contents of the preamble or training signal are known to the receiver) is sampled at time instant n resulting in a sample y[n]. In block 503, a signal candidate \hat{x}[n] is generated corresponding to the known symbol(s) of the training signal. In block 504, the nonlinearity modeling circuit 212 calculates the power of the signal candidate (e.g., as |\hat{x}[n]|²). In block 506, the nonlinear modeling circuit 212 accesses the LUT 302 to find the one of the values 304₁ . . . 304_{K} that is closest to |\hat{x}[n]|² (denoted 304ₖ). In block 508, 304ₖ is mapped to the value 306ₖ by the LUT 302. In block 510, the nonlinear modeling circuit 212 accesses the LUT 312 to find the one of the values 314₁ . . . 314_{K} that is closest to |\hat{x}[n]|² (denoted 314ₖ). In block 512, the value 314ₖ is mapped to 316ₖ by LUT 312. In block 514, the nonlinear estimation circuit 212 generates a reconstructed signal ŷ[n] based on the candidate signal and based on the values 306ₖ and 316ₖ from the LUTs 302 and 312 (e.g., using equation (3)). In block 516, the nonlinear estimation circuit 212 calculates the error values eₐₘ(|y[n]|²) and eₚₘ(|y[n]|²) based on the received signal y[n] and the reconstructed signal ŷ[n] (e.g., using equations 4 and 5) In block 518, the signal estimation circuit 212 adjusts the value 306ₖ based on eₐₘ(|y[n]|²) and adjusts the value 316ₖ based on eₚₘ(|y[n]|²) (e.g., according to equations (6) and (7) or (8) and (9)).

In an example implementation, the nonlinear distortion present in the received signal may be modeled as a function of the weighted sum of the current, past (i.e., samples already processed by nonlinearity estimation circuit 212) and/or future (i.e., buffered samples waiting to be processed by nonlinearity estimation circuit 212) instantaneous power (sampled square) of the baseband-equivalent input of a nonlinear circuit (e.g., 110 or 202). That is:

y[n]=x[n]·ƒ(|x[n]|²,|x[n−1]|², . . . ,|x[n−L]|²). (10)

The function ƒ( ) may be selected to be a function of the weighted sum of the squared samples:

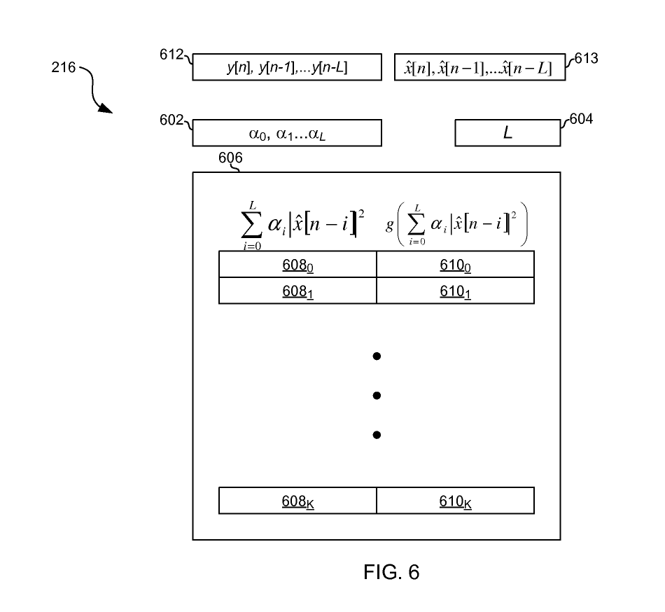

ƒ(|x[n]|²,|x[n−1]|², . . . ,|x[n−L]|²) [symbol] g(Σᵢ₌₀^{L}αᵢ|x[n−i]|²), (11)

where the function g( ) is in general a nonlinear function. Thus, this weighted-sum type model may be characterized by a memory depth parameter (L) (e.g., stored in a register 604 of memory 216), a coefficient vector parameter (αᵢ for i=0, 1, . . . , L) (e.g., stored in a register 602 of memory 216), a signal power parameter (Σᵢ₌₀^{L}αᵢ|x[n−i]|²), and a reconstructed signal distortion parameter (g (Σᵢ₌₀^{L}αᵢ|x[n−i] |²)). The function g( ) which may be implemented by a LUT that accommodates the nonlinear mapping of its input values to output values. For example, referring to FIG. 6, each entry of the LUT 606 maps a value of the signal power parameter (denoted 608ₖ for 0≦k≦K) to a corresponding value of the reconstructed signal distortion parameter (demoted 610ₖ).

In an example implementation, α₀ is set to 1 or to some constant in order to keep the linear gain of the model fixed. The function ƒ( ) describes the distortion applied to the signal. In general, ƒ( ) is a complex-valued function that captures the amplitude and phase distortion experienced by the current sample, where such amplitude and phase distortion depend on the instantaneous power (sampled square) of the current sample, one or more past samples, and/or one or more future samples. This nonlinear model has memory by definition which accounts for the behavior of practical amplifiers when operated around their saturation power.

Parameters of this model may be received by the receiver 200 from the transmitter 100 (e.g., during connection setup, in preambles, and/or the like) and/or adaptively learned by the nonlinearity estimation circuit 212. Such adaptation may be according to the measured nonlinear model errors. For example, using the least mean squares (LMS) algorithm, the error can be defined as follows:

e[n]=y[n]−\hat{x}[n]·g(Σᵢ₌₀^{L}αᵢ|\hat{x}[n−i]|²) (12)

The weights αᵢ, (for i=0, 1, . . . , L) may be adapted according to the following rule:

αᵢ⁽ⁿ⁾=αᵢ⁽ⁿ⁻¹⁾+μ·e[n]·\hat{x}*[n]·|\hat{x}[n−i]|²·g′*(Σᵢ₌₀^{L}αᵢ|\hat{x}[n−i]|²), (3)

where the asterisk superscript stands for the complex conjugate and g′( ) denotes the derivative of the nonlinear function g( ).

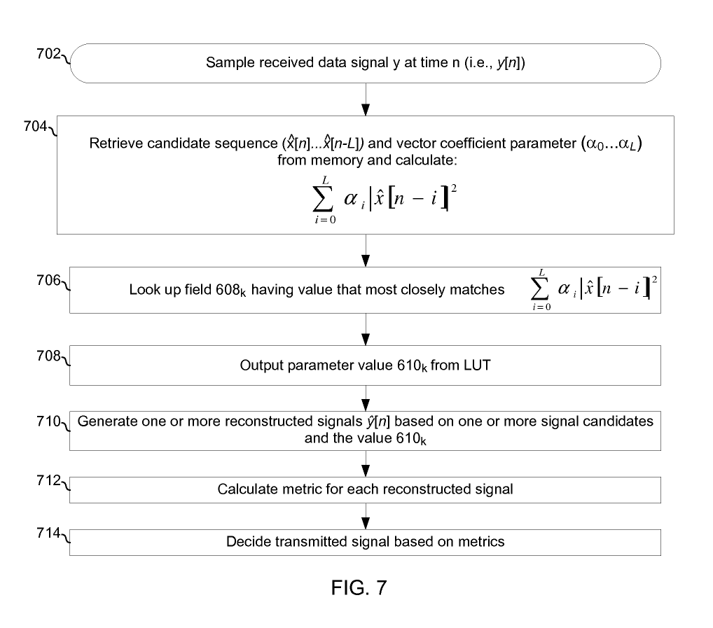

FIG. 7 is a flowchart illustrating an example process for signal reception using the nonlinear model of FIG. 6. In block 702, a received signal y is sampled at time instant n resulting in a sample y[n]. Samples of the received signal may be buffered in a register 612. In block 704, the candidate for the current time instant \hat{x}([n]), the candidate sequence determined during previous time instants (\hat{x}[n−1] . . . \hat{x}[n−L]), and the coefficient vector parameter (α₀ . . . α_{L}) are retrieved from memory (e.g., from registers 613 and 602 in memory 216) and are used to calculate the signal power parameter Σᵢ₌₀^{L}αᵢ|\hat{x}[n−i]|². In block 706, the nonlinear modeling circuit 212 accesses the LUT 606 to find the one of the values 608₀ . . . 608_{K} (denoted 608ₖ) that is closest to the value of the signal power parameter calculated in block 704. In block 708, the value 608k is mapped to value 610ₖ by the LUT 606. In block 710, the nonlinear estimation circuit 212 generates one or more reconstructed signals ŷ[n] based on the one or more signal candidates and based on the value 610ₖ from the LUT 606 (e.g., using equation (10)). In block 712, a metric is calculated for each of the reconstructed signals. Each of the metrics may be, for example, Euclidean distance between the received signal ŷ[n] and a corresponding one of the reconstructed signals ŷ[n]. In block 714, the symbol detection circuit 217 decides the most-likely transmitted signal based on the calculated metrics.

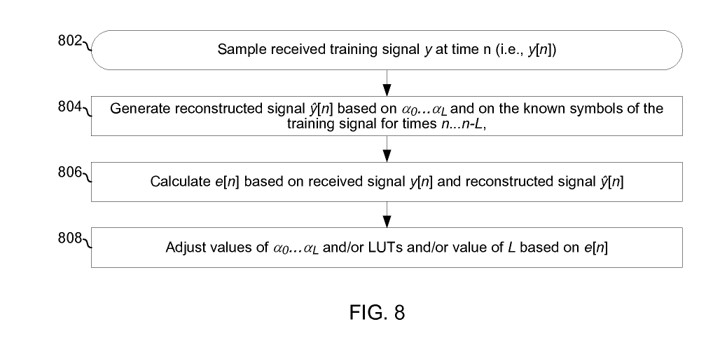

FIG. 8 is a flowchart illustrating an example process for signal reception using the nonlinear model of FIG. 6. In block 802, a received training signal y is sampled at time instant n resulting in a samples y[n]. In block 804, the nonlinear estimation circuit 212 generates (e.g., according to equations (10) and (11)) a reconstructed signal ŷ[n] based on the values of α₀ . . . α_{L} stored in register 602, and based on the transmitted symbols of the training signal x[n] . . . x[n−L] known by the receiver to correspond to the received signal at times n . . . n−L. In block 806, the nonlinear estimation circuit 212 calculates e[n] based on the received signal y[n] and based on the reconstructed signal ŷ[n] (e.g., according to equation 12). In block 808, the nonlinear estimation circuit 212 adjusts the value of L and/or the value(s) of one or more of the coefficients α₀ . . . α_{L} (e.g., according to equation 13). Similar to the error signals eₐₘ and eₚₘ discussed above for the composite AM/AM and AM/PM model, the error e[n] for the model described with reference to FIGS. 6 through 9 may be filtered and or weighted in a manner similar to described above with reference to equations (6) through (9).

A method in accordance with an implementation of this disclosure may comprise: in a receiver, receiving an inter-symbol correlated (ISC) signal that was generated by passage of symbols through a nonlinear circuit; and estimating said nonlinear circuit using a reconstruction of said ISC signal. The nonlinear circuit model may be used for detection. The ISC signal may modulate a single carrier or multi-carrier (OFDM) signal. The ISC signal may be a partial response signal generated via a partial response filter. The symbols may be N-QAM symbols where N is an integer. The detection may be based on maximum-likelihood (ML) and/or maximum a-posteriori (MAP). The method may be based on sequence estimation. The detection may be applied to recover said symbols and/or bits. The estimation of the nonlinear circuit may be based on known symbols and unknown symbols and different weights may be given for estimation based on the known and unknown symbols. The nonlinear model may be based on a combination of one or more of the following models: am/am, am/pm, memory-less polynomial, polynomial with memory, Volterra series, Rapp. The nonlinear model estimation may be adaptive. The adaptation rate may be affected by channel conditions. The nonlinear model may be updated by one or more error functions that represent a measure of distance between the reconstructed ISC signal and the received signal. The error functions may be weighted according to the signal levels. The known symbols may consist of a training sequence and/or preamble designated for covering nonlinearity dynamic range. The estimation of nonlinear circuit may be communicated to the remote transmitter. The estimation of nonlinear circuit may be used by the remote transmitter to configure transmitter circuit and to adapt the transmitted signal in accordance with the estimated nonlinear model. The nonlinear circuit estimation may be use interpolation and/or extrapolation. The receiver may comprise a pre-distortion circuit and the composite nonlinear distortion may be the result of the concatenation of the pre-distortion circuit and the nonlinear circuit. Estimating composite nonlinearity may using a reconstruction of the ISC signal. The pre-distortion may be configured to minimize memory of the composite nonlinear distortion.

In accordance with an example implementation of this disclosure, a receiver may comprise a signal reconstruction circuit (e.g., 206) and a nonlinearity modeling circuit (e.g., 212). The nonlinearity modeling circuit may be operable to generate a look-up table (LUT)-based model (e.g., the composite model described with reference to FIGS. 3 through 5 or the model with memory described with reference to FIGS. 6-8) of nonlinear distortion present in a received signal. An entry of the LUT may comprise a signal power parameter value (e.g., 304ₖ, 314ₖ, or 608ₖ) and a distortion parameter value (e.g., 306ₖ, 316ₖ, or 610ₖ). The signal reconstruction circuit may be operable to generate one or more candidates for a transmitted signal corresponding to the received signal. The signal reconstruction circuit may be operable to distort the one or more candidates according to the model, the distortion resulting in one or more reconstructed signals. The signal reconstruction circuit may be operable to decide a best one of the candidates based on the one or more reconstructed signals. The signal power parameter value may correspond to the instantaneous power of a symbol or to a weighted sum of the instantaneous power of each of a plurality of past, current, and/or future symbols. The distortion parameter value may comprises an amplitude-to-amplitude distortion value. The nonlinearity modeling circuitry may be operable to determine a magnitude error between the received signal and the reconstructed signal, and adjust the amplitude-to-amplitude distortion value based on the magnitude error. The distortion parameter value may comprise an amplitude-to-phase distortion value. The nonlinearity modeling circuitry may be operable to determine a phase error between the received signal and the reconstructed signal, and adjust the amplitude-to-phase distortion value based on the phase error. The distortion parameter value may be based on a weighted sum of the instantaneous power of each a plurality of past, current, and/or future symbols. The nonlinearity modeling circuit may be operable to generate the weighted sum based on a coefficient vector parameter associated with the LUT. The nonlinearity modeling circuit may be operable to determine an error between the received signal and the reconstructed signal, and adjust the coefficient vector parameter based on the error.

The present method and/or system may be realized in hardware, software, or a combination of hardware and software. The present methods and/or systems may be realized in a centralized fashion in at least one computing system, or in a distributed fashion where different elements are spread across several interconnected computing systems. Any kind of computing system or other apparatus adapted for carrying out the methods described herein is suited. A typical combination of hardware and software may be a general-purpose computing system with a program or other code that, when being loaded and executed, controls the computing system such that it carries out the methods described herein. Another typical implementation may comprise an application specific integrated circuit or chip. Some implementations may comprise a non-transitory machine-readable (e.g., computer readable) medium (e.g., FLASH drive, optical disk, magnetic storage disk, or the like) having stored thereon one or more lines of code executable by a machine, thereby causing the machine to perform processes as described herein.

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, it is intended that the present method and/or system not be limited to the particular implementations disclosed, but that the present method and/or system will include all implementations falling within the scope of the appended claims.

What is claimed is:

1. A system comprising:
a signal reconstruction circuit and a nonlinearity modeling circuit, wherein:
said nonlinearity modeling circuit is operable to generate a look-up table (LUT)-based model of nonlinear distortion present in a received signal, wherein an entry of said LUT comprises a signal power parameter value and a distortion parameter value;
said signal reconstruction circuit is operable to generate one or more candidates for a transmitted signal corresponding to said received signal; and
said signal reconstruction circuit is operable to distort said one or more candidates according to said model, said distortion resulting in one or more reconstructed signals.

2. The system of claim 1, wherein said signal power parameter value corresponds to the instantaneous power of a symbol.

3. The system of claim 1, wherein said signal power parameter value corresponds to a weighted sum of the instantaneous power of each of a plurality of past, current, and/or future symbols.

4. The system of claim 1, wherein said distortion parameter value comprises an amplitude-to-amplitude distortion value.

5. The system of claim 1, wherein said nonlinearity modeling circuit is operable to:
determine a magnitude error between said received signal and said one or more of the reconstructed signals; and
adjust said amplitude-to-amplitude distortion value based on said magnitude error.

6. The system of claim 1, wherein said distortion parameter value comprises an amplitude-to-phase distortion value.

7. The system of claim 1, wherein said nonlinearity modeling circuit is operable to:
determine a phase error between said received signal and said reconstructed signal; and
adjust said amplitude-to-phase distortion value based on said phase error.

8. The system of claim 1, wherein said distortion parameter value is based on a weighted sum of the instantaneous power of each a plurality of past, current, and/or future symbols.

9. The system of claim 8, wherein said nonlinearity modeling circuit is operable generate said weighted sum based on a coefficient vector parameter associated with said LUT.

10. The system of claim 9, wherein said nonlinearity modeling circuit is operable to:
determine an error between said received signal and said one or more reconstructed signals; and
adjust said coefficient vector parameter based on said error.

11. The system of claim 1, comprising a bits recovery circuit, wherein:
said signal reconstruction circuit is operable to receive an output of said bits recovery circuit for iterative processing of said received signal.

12. A method comprising:
performing by a signal reconstruction circuit and a nonlinearity modeling circuit of a receiver:
generating a look-up table (LUT)-based model of nonlinear distortion present in a received signal, wherein an entry of said LUT comprises a signal power parameter value and a distortion parameter value;
generating one or more candidates for a transmitted signal corresponding to said received signal; and
distorting said one or more candidates according to said model, said distortion resulting in one or more reconstructed signals.

13. The method of claim 12, wherein said signal power parameter value corresponds to the instantaneous power of a symbol.

14. The method of claim 12, wherein said signal power parameter value corresponds to a weighted sum of the instantaneous power of each of a plurality of past, current, and/or future symbols.

15. The method of claim 12, wherein said distortion parameter value comprises an amplitude-to-amplitude distortion value.

16. The method of claim 12, comprising:
performing by said signal reconstruction circuit and a nonlinearity modeling circuit:
determining a magnitude error between said received signal and said reconstructed signal; and
adjusting said amplitude-to-amplitude distortion value based on said magnitude error.

17. The method of claim 12, wherein said distortion parameter value comprises an amplitude-to-phase distortion value.

18. The method of claim 12, comprising:
performing by said signal reconstruction circuit and a nonlinearity modeling circuit:
determining a phase error between said received signal and said reconstructed signal; and
adjusting said amplitude-to-phase distortion value based on said phase error.

19. The method of claim 12, wherein said distortion parameter value is based on a weighted sum of the instantaneous power of each a plurality of past, current, and/or future symbols.

20. The method of claim 19, wherein said nonlinearity modeling circuit is operable generate said weighted sum based on a coefficient vector parameter associated with said LUT.

21. The method of claim 20, comprising:
performing by said signal reconstruction circuit and a nonlinearity modeling circuit:
determining an error between said received signal and said one or more reconstructed signal; and
adjusting said coefficient vector parameter based on said error.

22. The method of claim 12, comprising performing by said signal reconstruction circuit and a nonlinearity modeling circuit:
iteratively processing of said received signal, wherein each subsequent iteration on a particular symbol uses an output of a bits recovery circuitry from a previous iteration.
